(19) United States
(12) Patent Application Publication
(10) Pub. No.: US 2011/0175626 A1
(43) Pub. Date: Jul. 21, 2011

(54) PORTABLE DEVICE WITH PROXIMITY SENSORS

(75) Inventors: Bang-Won Lee, Yongin-si (KR); Chul-Yong Joung, Yongin-si (KR); Sang-Jin Lee, Yongin-si (KR); Yong-Hwan Kim, Yongin-si (KR); Jin-Woo Chung, Yongin-si (KR); Jae-Surk Hong, Yongin-si (KR); Duck-Young Jung, Yongin-si (KR); Young-Ho Shin, Yongin-si (KR)

(73) Assignee: ATLAB INC., Yongin-si (KR)

(21) Appl. No.: 13/122,188

(22) PCT Filed: Mar. 26, 2009
(86) PCT No.: PCT/KR2009/001534

§ 371 Date: Apr. 1, 2011

(30) Foreign Application Priority Data
Oct. 7, 2008 (KR) 10-2008-0098393

(51) Int. Cl. G01R 27/04

(52) U.S. Cl. 324/629

(57) ABSTRACT

A portable device with a proximity sensor is provided. The portable device with a proximity sensor of the present invention includes a shielding plate for shielding impedance applied in a direction opposite to the direction that the proximity sensor detects the proximity such that the proximity sensor is not affected by a change in the surrounding environment and can detect the proximity at the same sensitivity at all times. Moreover, when the portable device is placed upside down on a conductive surface that causes low impedance, a proximity sensor placed adjacent to the conductive surface is deactivated to prevent malfunction.

### TECHNICAL FIELD

The present invention relates to a portable device with a proximity sensor, and more particularly, to a portable device with an impedance sensing-type proximity sensor.

### BACKGROUND ART

A proximity sensor is a sensor capable of detecting the presence of nearby objects without any physical contact, and there are a variety of proximity sensors based on methods of detecting nearby objects.

Among the proximity sensors, an impedance sensing-type proximity sensor that detects a nearby object by detecting a change in impedance is structurally similar to an impedance sensing-type touch sensor. That is, the impedance sensing-type touch sensor can be used as a proximity sensor by setting the sensitivity of the impedance sensing-type touch sensor to a high level. Examples of these impedance sensing-type touch sensor and proximity sensor are disclosed in Korean Patent Publication No. 2008-0047332. The impedance sensing-type proximity sensor is very suitable to be used together with a touch sensor in a portable device. Moreover, since it is easy to detect an object that causes low impedance, it is possible to easily detect the proximity of a user, not all nearby objects. However, some of the proximity sensors including the impedance sensing-type proximity sensor have a problem that it is difficult to specify a sensing direction. Furthermore, since the proximity sensor detects a nearby object, not an object that comes in contact with the sensor, and the surrounding environment of the portable device is changed very often, it is most likely that the proximity sensor used in the portable device causes malfunction. For example, if a portable device including a proximity sensor for detecting the proximity of a user is placed on a conductive plate that causes low impedance, it determines that the user is approaching the sensor based on a reduction in impedance, even if he or she does not approach the sensor, which results in malfunction. Therefore, when the proximity sensor is used in the portable device, it is necessary to prevent malfunction caused by a change in the surrounding environment.

### DISCLOSURE

### Technical Problem

It is, therefore, an object of the present invention to provide a portable device with a proximity sensor which can prevent malfunction due to a change in the surrounding environment.

### Technical Solution

In accordance with one aspect of the present invention, a portable device with a proximity sensor includes: upper and lower cases; at least one printed circuit board placed between the upper and lower cases and including a controller; at least one first proximity sensor placed between the upper case and the at least one printed circuit board and configured to detect impedance; at least one second proximity sensor placed between the lower case and the at least one printed circuit board and configured to detect impedance; and at least one shielding means placed between the at least one first proximity sensor and the at least one second proximity sensor such that impedance applied through the lower case is prevented from being applied to the first proximity sensor and impedance applied through the upper case is prevented from being applied to the second proximity sensor.

The at least one shielding means may be a conductive plate electrically connected to a ground voltage.

The portable device may further include an insulating plate having a low dielectric constant and placed between the at least one shielding means and the at least one printed circuit board.

The at least one shielding means may be an insulating plate having a low dielectric constant.

The at least one shielding means may form an empty space of a predetermined distance between the first and second proximity sensors.

When the printed circuit board is a multi-layered printed circuit board, the at least one shielding means may be implemented as one layer of the multi-layered printed circuit board.

When there are provided a plurality of printed circuit boards, the at least one shielding means may be placed between the plurality of printed circuit boards.

The at least one shielding means may be placed between the at least one printed circuit board and the first and second proximity sensors, respectively.

The controller may compare impedance values detected by the first and second proximity sensors for a predetermined period of time, deactivate the first proximity sensor if the impedance value detected by the first proximity sensor is smaller than the impedance value detected by the second proximity sensor, and deactivate the second proximity sensor if the impedance value detected by the first proximity sensor is equal to or greater than the impedance value detected by the second proximity sensor.

The controller may compare changes in impedance values measured by the first and second proximity sensors a plurality of times for a predetermined period of time, deactivate the second proximity sensor if the change in impedance values detected by the first proximity sensor is greater than the change in impedance values detected by the second proximity sensor, and deactivate the first proximity sensor if the change in impedance values detected by the first proximity sensor is equal to or smaller than the change in impedance values detected by the second proximity sensor.

When the first proximity sensors and the second proximity sensors are provided in plural, the controller may deactivate the plurality of second proximity sensors if all of the plurality of first proximity sensors detect proximity within a predetermined period of time, and deactivate the plurality of first proximity sensors if all of the plurality of second proximity sensors detect proximity within a predetermined period of time.

When the first proximity sensors and the second proximity sensors are provided in plural, the controller may deactivate the plurality of first proximity sensors if the sum of impedances detected by the plurality of first proximity sensors is smaller than a first reference impedance value, and deactivate the plurality of second proximity sensors if the sum of impedances detected by the plurality of second proximity sensors is smaller than a second reference impedance value.

The first and second reference impedance values may be the sum of average impedance values previously detected by the plurality of first proximity sensors a plurality of times and the sum of average impedance values previously detected by the plurality of second proximity sensors a plurality of times, respectively.

When the first proximity sensors and the second proximity sensors are provided in plural, the controller may deactivate the plurality of first proximity sensors if the difference in impedance detected by the plurality of first proximity sensors is equal to or smaller than a first reference impedance value, and deactivate the plurality of second proximity sensors if the difference in impedance detected by the plurality of second proximity sensors is equal to or smaller than a second reference impedance value.

The first and second reference impedance values may be the difference of average impedance values previously detected by the plurality of first proximity sensors a plurality of times and the difference of average impedance values previously detected by the plurality of second proximity sensors a plurality of times, respectively.

When the first proximity sensors and the second proximity sensors are provided in plural, the plurality of first proximity sensors and the plurality of second proximity sensors may be arranged in the form of a matrix, respectively.

The controller may determine an approach direction of a user according to the order that the plurality of first and second proximity sensors detect proximity of the user.

The first and second proximity sensors may be used as touch sensors during deactivation.

In accordance with another aspect of the present invention, a portable device with a proximity sensor includes: upper and lower cases; at least one printed circuit board placed between the upper and lower cases and including a controller; a plurality of proximity sensors placed between the upper case and the at least one printed circuit board and configured to detect impedance; and at least one shielding means placed between the plurality of proximity sensors and the at least one printed circuit board such that impedance applied through the lower case is prevented from being applied to the plurality of proximity sensors.

### Advantageous Effects

Accordingly, a portable device with a proximity sensor of the present invention includes a shielding plate for shielding impedance applied in a direction opposite to the direction that the proximity sensor detects the proximity such that the proximity sensor is not affected by a change in the surrounding environment and can detect the proximity at the same sensitivity at all times. Moreover, if the portable device is placed upside down on a conductive surface that causes low impedance, a proximity sensor placed on the upper surface of the portable device is deactivated so as to prevent malfunction and reduce power consumption. Furthermore, a proximity sensor can be also provided on the lower surface of the portable device so as to detect the proximity of a user even when the portable device is turned upside down.

### DESCRIPTION OF DRAWINGS

FIG. 1 is a diagram of a portable device with a proximity sensor in accordance with a first exemplary embodiment of the present invention;

FIG. 2 is a diagram of a portable device with a proximity sensor in accordance with a second exemplary embodiment of the present invention;

FIG. 3 is a diagram of a portable device with a proximity sensor in accordance with a third exemplary embodiment of the present invention;

FIGS. 4 and 5 are flowcharts illustrating methods of detecting proximity using the portable device of FIG. 3; and

FIG. 6 is a diagram of a portable device with a proximity sensor in accordance with a fourth exemplary embodiment of the present invention.

### MODE FOR INVENTION

Hereinafter, a portable device with a proximity sensor in accordance with exemplary embodiments of the present invention will be described with reference to the accompanying drawings.

While the following description is of an example in which the proximity sensor is an impedance sensing-type proximity sensor, the present invention is not limited to the impedance sensing-type proximity sensor.

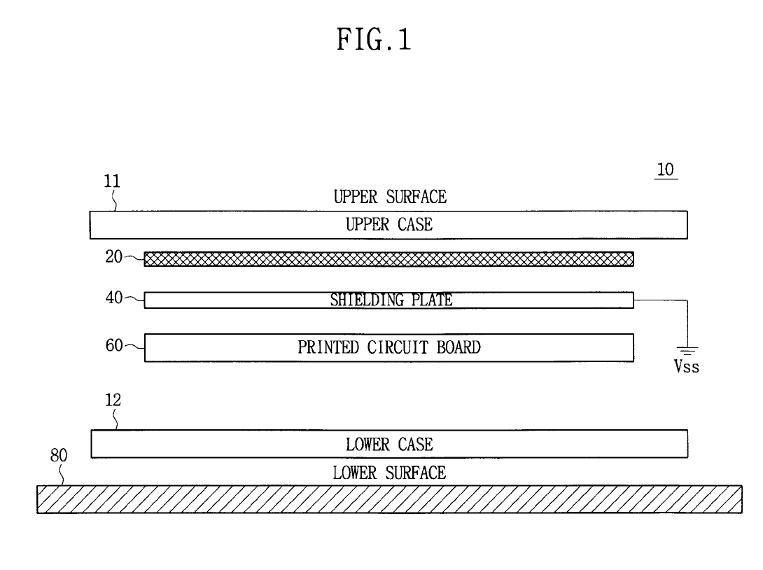

FIG. 1 is a diagram of a portable device including a shielding plate for preventing malfunction of a proximity sensor in accordance with a first exemplary embodiment of the present invention.

The portable device 10 of FIG. 1 includes an upper case 11, a lower case 12, and a proximity sensor 20 placed beneath the upper case 11 to detect the proximity.

Most portable devices have a user interface placed on the upper case 11, through which all operations are performed. Accordingly, it is desirable that the direction that the proximity sensor 20 detects the proximity of a user should be limited to the upper surface. That is, the proximity sensor 20 should not detect an object approaching the lower surface. Accordingly, the proximity sensor 20 is placed beneath the upper case 11 as shown in FIG. 1 such that it can easily detect the proximity of a user to the upper surface. A shielding plate 40 is placed beneath the proximity sensor 20 such that the proximity sensor 20 cannot detect a change in impedance of the lower surface, but can detect a change in impedance of only the upper surface. The shielding plate 40 is a conductive plate electrically connected to a ground voltage Vss.

Since the shielding plate 40 is electrically connected to the ground voltage Vss, if the portable device 10 is placed on a conductive surface 80, the change in impedance applied through the lower case 12 is shielded by the shielding plate 40, and thus the proximity sensor 20 can detect the proximity of a user to the upper surface at the same sensitivity, regardless of the change in impedance of the lower surface.

The proximity sensor 20 may be attached to the upper case 11 by adhesive means such as adhesive tape (not shown), and the shielding plate 40 may be attached to the proximity sensor 20 by adhesive means such as an insulating tape (not shown). Since the shielding plate 40 is electrically connected to the ground voltage Vss, it should not come in contact with the proximity sensor 20. That is, since the proximity sensor 20 and the shielding plate 40 should be insulated from each other, it is necessary to use adhesive means such as insulating tape. However, since the shielding plate 40 is provided to prevent the detection of a change in impedance of the lower surface, it may not be in close contact with the lower surface of the proximity sensor 20. That is, the shielding plate 40 may be spaced from the proximity sensor 20 at a predetermined distance (for example, 2 mm) even without the use of the adhesive means such as insulating tape. Moreover, the shielding plate 40 may be placed on the upper surface of the lower case 12, if necessary. However, the portable device 10 includes a printed circuit board (PCB) 60 on which various circuits such as a controller for performing a predetermined operation are provided. The printed circuit board 60 may cause a change in impedance due to electromagnetic waves generated by the various circuits on the printed circuit board 60, thus generating noise that causes the proximity sensor 20 to malfunction. Therefore, if the shielding plate 40 is placed between the proximity sensor 20 and the printed circuit board 60, it prevents the detection of a change in impedance caused in the printed circuit board 60 as well as a change in impedance of the lower surface such that the proximity sensor 20 can stably detect the change in impedance of the upper surface. Moreover, when the printed circuit board 60 is a multi-layered board, the shielding plate 40 may be implemented as one layer of the printed circuit board 60.

While the portable device 10 of FIG. 1 can prevent malfunction due to the change in impedance applied through the lower case 12 with the use of the shielding plate 40, it is not guaranteed that the portable device 10 will be arranged in a fixed direction at all times. That is, if the upper case 11 is placed toward the conductive surface 80, the direction that the proximity sensor 20 of the portable device 10 will detect is toward the conductive surface 80, and therefore the proximity sensor 20 detects a change in impedance due to the conductive surface 80, which results in malfunction.

If the shielding plate 40 is mounted in such a direction that the proximity sensor 20 will detect to prevent the malfunction, the proximity sensor 20 cannot detect the proximity of a user and, as a result, it cannot perform even its primary function. Although FIG. 1 shows the proximity sensor 20 having a size equal to or greater than that of the printed circuit board 60 for convenience of description, the size of the proximity sensor 20 may be smaller than that of the printed circuit board 60. In this case, it is possible to reduce the size of the shielding plate 40 in accordance with that of the proximity sensor 20. Moreover, the proximity sensor 20 may not be arranged in parallel on the top of the printed circuit board 60. For example, the proximity sensor 20 may be arranged on a top side of the printed circuit board 60 or in a diagonal direction. When the proximity sensor 20 is arranged on the top side of the printed circuit board 60 or in the diagonal direction, the shielding plate 40 may be substituted for a space.

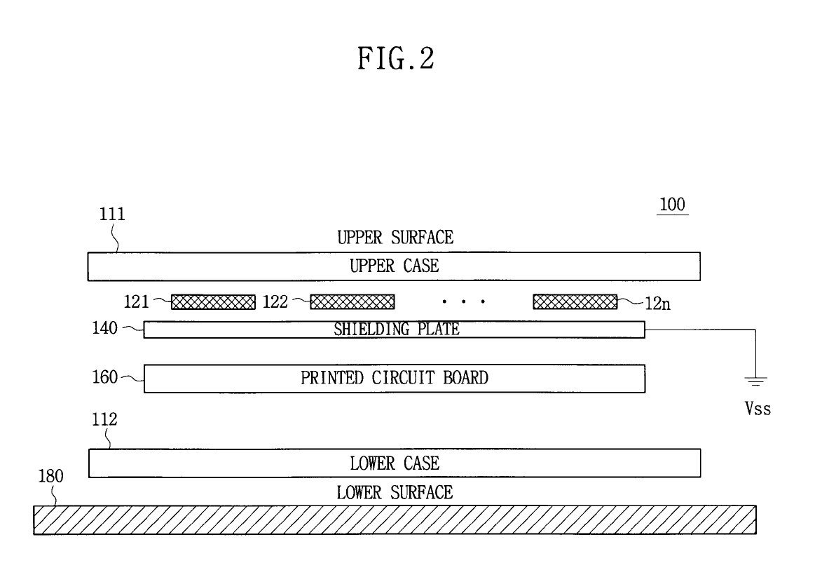

FIG. 2 is a diagram of a portable device with a proximity sensor in accordance with a second exemplary embodiment of the present invention. The portable device 100 of FIG. 2 includes a plurality of proximity sensors 121 to 12n. In FIG. 1, one proximity sensor 20 is provided beneath the upper case 11 to detect a change in impedance of the upper surface, thus detecting the proximity of a user. However, the portable device 100 of FIG. 2 includes the plurality of proximity sensors 121 to 12n placed beneath an upper case 111 such that the plurality of proximity sensors 121 to 12n can detect the proximity of a user, respectively. A shielding plate 140 is provided beneath the plurality of proximity sensors 121 to 12n such that all of the plurality of proximity sensors 121 to 12n may not be affected by the change in impedance of the lower surface. Similarly to the shielding plate 40 of FIG. 1, the shielding plate 140 is a conductive plate electrically connected to the ground voltage Vss such that the change in impedance of the lower surface or the change in impedance due to electromagnetic waves generated by various circuits on a printed circuit board 160 may not affect the proximity sensors 121 to 12n.

Since the portable device 100 of FIG. 2 includes the plurality of proximity sensors 121 to 12n that individually detect the proximity of a user, differently from that of the portable device 10 of FIG. 1, the plurality of proximity sensors 121 to 12n sequentially detect an approach direction of a user or only a portion of the plurality of proximity sensors 121 to 12n detect the proximity of a user. However, if the upper case 111 of the portable device 100 is placed toward a conductive surface 180, all or substantially all of the plurality of proximity sensors 121 to 12n detect the proximity of a user at approximately the same time. Accordingly, if all of the plurality of proximity sensors 121 to 12n detect the proximity of a user within a predetermined period of time (for example, 1 msec), if the sum of impedances detected by all of the plurality of proximity sensors 121 to 12n is smaller than a reference impedance value (IMPth), or if the difference in impedance detected by all of the plurality of proximity sensors 121 to 12n is greater than a predetermined value, it is not determined that the user approaches the portable device 100 of FIG. 2, but it is determined that the portable device 100 is placed on the conductive surface 180, thus performing an operation different from the case in which the user approaches the portable device 100. Here, the reference impedance value (IMPth) may be set to the sum of average impedances previously detected by the individual proximity sensors m (m being a natural number) times (for example, 10 times). If so, the reference impedance value (IMPth) is changed by the change in the surrounding environment and, therefore, it is easy to detect a sudden change in impedance, such as the case in which the portable device 100 is placed on the conductive surface 180. In this case, there are various methods of measuring the impedance and, for example, a touch and proximity sensor capable of converting a change in impedance into a digital value is disclosed in Korean Patent Publication No. 2008-0047332.

The function of determining whether the user approaches the portable device 100 or whether the portable device 100 is placed on the conductive surface 180 and performing different operations may be performed by a controller mounted on the printed circuit board 160.

For example, when the portable device 100 is a remote controller, if the proximity of a user is detected, the controller allows the remote controller to be changed from a deep power down state to a standby state. Otherwise, in the case of a remote controller using radio frequency (for example, Bluetooth), the controller generates a synchronization signal for synchronizing the clock with a frequency receiver corresponding to the remote controller such that the remote controller can provide a rapid response when a user comes in direct contact with the remote controller and operates it. Moreover, if the proximity of a user is detected, the controller generates a signal for activating other sensors such as a touch sensor (not shown) or for changing operation mode of the proximity sensor from proximity sensing to touch sensing included in the portable device 100 such that the sensors are activated immediately. That is, it is possible to allow the portable device 100 to immediately respond to the user's command before the user comes in direct contact with the portable device 100. If the user does not approach the portable device 100, the controller may allow the portable device 100 to enter a maximum power saving state such as the deep power down state or deactivate the sensors other than the proximity sensors 121 to 12n, thus reducing power consumption and preventing malfunction. Moreover, if it is determined that the upper case 111 of the portable device 100 is placed toward the conductive surface 180, the controller may reduce the power consumption, such as when the user does not approach the portable device 100, and may further reduce the power consumed by the proximity sensors 121 to 12n by deactivating the detection function of all or a portion of the proximity sensors 121 to 12n or by prolonging the detection period.

Moreover, since the portable device 100 of FIG. 2 includes the plurality of proximity sensors 121 to 12n, the controller may detect the approach direction of a user according to the order that the plurality of proximity sensors 121 to 12n detect the proximity of a user. Accordingly, the controller may allow the portable device 100 to perform different operations in accordance with the approach direction of a user. In this case, it is preferable that the plurality of proximity sensors 121 to 12n be arranged in the form of a matrix so as to detect the approach direction of a user.

Furthermore, it is possible to use an impedance sensing-type touch sensor as a proximity sensor by setting the sensitivity of the impedance sensing-type touch sensor at a high level as mentioned above. Accordingly, the portable device 100 of FIG. 2 may include a plurality of touch sensors and use them as the proximity sensors 121 to 12n of FIG. 2 by adjusting the sensitivity of the plurality of touch sensors. Since the proximity sensors 121 to 12n detect the proximity of a user and the touch sensors detect the direct contact of a user, the proximity sensors 121 to 12n and the touch sensors are not used at the same time. Accordingly, if a touch is not detected for more than a predetermined time (for example, 10 seconds) in a portable device including the touch sensors without the use of the proximity sensor, or if the proximity of a user is not detected in a portable device including the touch sensors and only one proximity sensor, it is possible to use the touch sensors as the proximity sensors 121 to 12n by setting the sensitivity of the touch sensor at a high level. Alternatively, instead of setting the sensitivity at a high level, it is possible to increase the sensitivity of a plurality of touch sensors by electrically connecting them to each other to increase the sensing area, thus using them as the proximity sensors.

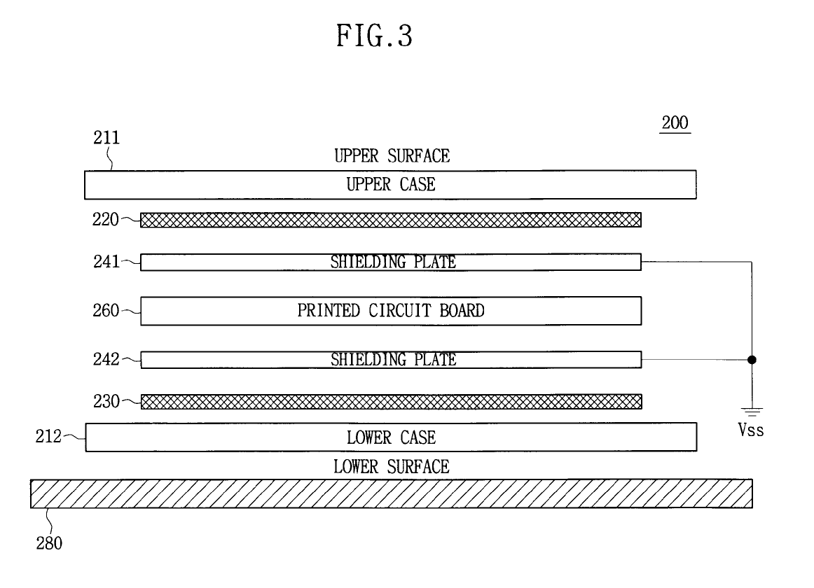

FIG. 3 is a diagram of a portable device with a proximity sensor in accordance with a third exemplary embodiment of the present invention. The portable device 200 of FIG. 3 includes first and second proximity sensors 220 and 230 placed beneath an upper case 211 and on a lower case 212, respectively. Moreover, the portable device 200 includes upper and lower shielding plates 241 and 242 placed between the first proximity sensor 220 and a printed circuit board 260 and between the second proximity sensor 230 and the printed circuit board 260, respectively. The shielding plates 241 and 242 are conductive plates electrically connected to a ground voltage Vss. Like the shielding plate 40 of FIG. 1, the upper shielding plate 241 prevents a change in impedance due to electromagnetic waves generated by various circuits on the printed circuit board 260 from affecting the first proximity sensor 220. The lower shielding plate 242 prevents a change in impedance of the printed circuit board 260 from affecting the second proximity sensor 230. Therefore, the portable device 200 of FIG. 3 including the first and second proximity sensors 220 and 230 can detect all of the changes in impedance of the upper surface and lower surface. Meanwhile, the conductive plates being used as the shielding plates 241 and 242 may be substituted with a structure in which low permittivity materials such as air are provided at a predetermined distance to minimize the change in impedance. Especially, in the case of a proximity sensor detecting a change in capacitance, insulating plates having a low permittivity may be used as the shielding plates 241 and 242 to reduce the change in capacitance. Since air has a low permittivity as mentioned above, a predetermined distance (for example, 3 mm) may be maintained between the proximity sensors 220 and 230 and the printed circuit board 260 as shielding means instead of the shielding plates 241 and 242. Moreover, when the first and second proximity sensors 220 and 230 are placed on the top and bottom of the printed circuit board 260 in a diagonal direction, the shielding plates 241 and 242 may of course be used in place of the predetermined distance.

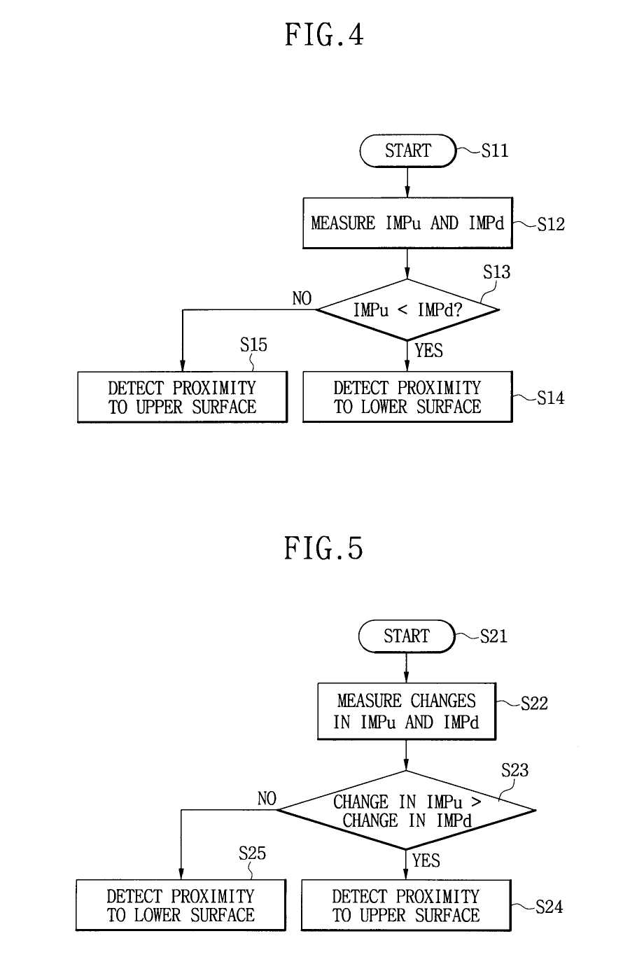

FIGS. 4 and 5 are flowcharts illustrating methods of detecting proximity using the portable device of FIG. 3. First, the method of detecting proximity of FIG. 4 will be described below. When the portable device 200 is placed on the conductive surface 280, measured impedances of proximity sensors 220 and 230 are lower than that caused when the portable device 200 is placed on wood or glass or lower than that caused when a user approached the portable device 200. Accordingly, the proximity sensors 220 and 230 measure the impedances for a longer period of time and, if one of the measured values is smaller than a predetermined reference impedance value, it is determined that the corresponding surface of the portable device 200 is placed on the conductive surface 280.

Accordingly, the portable device 200 measures the impedances of the upper surface and the lower surface for a predetermined period of time (for example, 10 minutes) using the first and second proximity sensors 220 and 230 in step S12. In this case, the time that the first and second proximity sensors 220 and 230 detect is set to be longer than the time that a user approaches in the portable devices 10 and 100 of FIGS. 1 and 2. The controller of the portable device 200 compares an upper impedance value IMPu detected by the first proximity sensor 220 and a lower impedance value IMPd detected by the second proximity sensor 230 in step S13. If the upper impedance value IMPu is smaller than the lower impedance value IMPd, it is determined that the upper case 211 of the portable device 200 is placed toward the conductive surface 280. Therefore, the controller allows only the second proximity sensor 230 to detect the proximity of a user and ignores the operation of the first proximity sensor 220 or deactivates the first proximity sensor 220, thus reducing the power consumption in step S14. However, if the upper impedance value IMPu is equal to or greater than the lower impedance value IMPd, it may be determined that the lower case 212 of the portable device 200 is placed toward the conductive surface 280 and, therefore, the controller allows only the first proximity sensor 220 to detect the proximity of a user in step S15.

The proximity detecting method of FIG. 4 can effectively detect the proximity only when the portable device 200 is placed on the conductive surface 280; however, if the user holds the portable device 200 in one hand and the other hand approaches the portable device 200, this method is not useful. Therefore, it is necessary to consider the case in which the user holds the portable device 200 in his or her hand.

FIG. 5 shows a method of detecting proximity which can be used when the user holds the portable device 200 in his or her hand. The portable device 200 measures the impedances for a predetermined period of time shorter than that of FIG. 4 (for example, 1 msec) in step S22, and the controller of the portable device 200 compares changes in impedance values measured for a predetermined period of time (for example, 1 sec) in step S23. Since the method of FIG. 5 employs the first and second proximity sensors 220 and 230 the same as the method of FIG. 4, the controller of the portable device 200 compares the change in the upper impedance value IMPu detected by the first proximity sensor 220 with the change in the lower impedance value IMPd detected by the second proximity sensor 230. If the change in the upper impedance value IMPu is greater than the change in the lower impedance value IMPd, it may be determined that the user's hand moves over the upper surface of the portable device 200. Therefore, the controller allows only the first proximity sensor 220 to detect the proximity of the user and ignores the operation of the second proximity sensor 230 or deactivates the second proximity sensor 230 in step S24. However, if the change in the upper impedance value IMPu is equal to or smaller than the change in the lower impedance value IMPd, it may be determined that the user's hand moves over the lower surface of the portable device 200 and, therefore, the controller allows only the second proximity sensor 230 to detect the proximity of the user in step S25. Moreover, when the portable device 200 is a mobile phone, for example, if the user makes a call holding the mobile phone in his or her hand, a microprocessor unit (MPU) included in the mobile phone may deactivate all of the proximity sensors. Furthermore, when the proximity sensors are also used as the touch sensors, the proximity sensors may be deactivated by detecting the contact.

Although the method of FIG. 4 and that of FIG. 5 have been described separately as individual methods of detecting proximity, it will be apparent that it is possible to use both methods of FIGS. 4 and 5 in combination in terms of various conditions under which the portable device 200 is used.

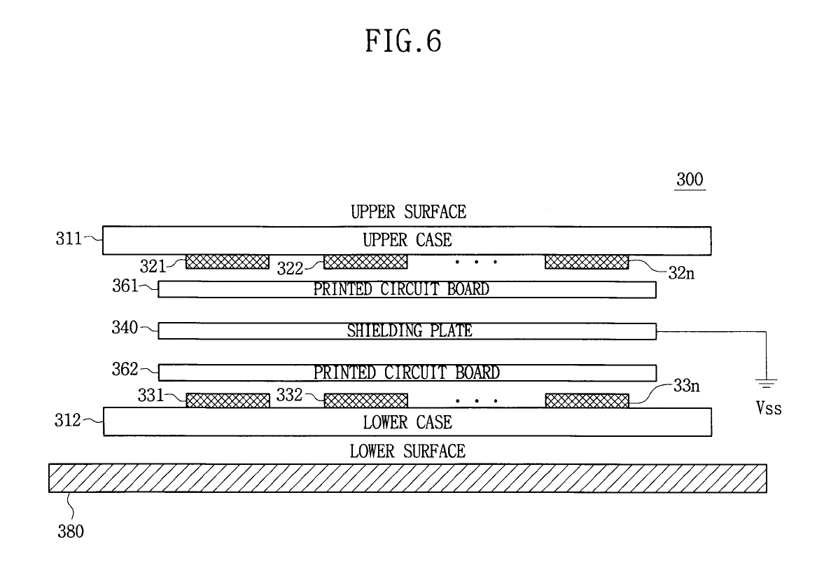

FIG. 6 is a diagram of a portable device with a proximity sensor in accordance with a fourth exemplary embodiment of the present invention. The portable device 300 of FIG. 6 includes an upper case 311, a lower case 312, a plurality of first proximity sensors 321 to 32n placed beneath the upper case 311 and detecting the proximity of a user to the upper surface, and a plurality of second proximity sensors 331 to 33n placed on the lower case 312 and detecting the proximity of a user to the lower surface. Unlike FIGS. 1 to 3, FIG. 6 shows the first and second proximity sensors 321 to 32n and 331 to 33n which are in close contact with the upper and lower cases 311 and 312, respectively. The first and second proximity sensors 321 to 32n and 331 to 33n of FIG. 6 may be spaced a predetermined distance from the upper and lower cases 311 and 312, respectively; however, it is preferable that the first and second proximity sensors 321 to 32n and 331 to 33n be in close contact with the upper and lower cases 311 and 312 so as to easily detect the impedances of the upper and lower surfaces, if the upper and lower cases 311 and 312 are formed of a material that does not cause a low impedance.

Moreover, the portable device 300 of FIG. 6 includes two printed circuit boards 361 and 362 placed at the top and bottom. The downsizing of the portable device 300 may be a very important factor. Accordingly, the portable device 300 may include a plurality of printed circuit boards 361 and 362 for the downsizing of the portable device 300.

A shielding plate 340 is placed between the two printed circuit boards 361 and 362. The shielding plate 340 in accordance with this exemplary embodiment of the present invention is provided such that the impedance of the lower surface may not affect the first proximity sensors 321 to 32n and that of the upper surface may not affect the second proximity sensors 331 to 33n. Therefore, the first and second proximity sensors 321 to 32n and 331 to 33n can detect the proximity without the influence of the impedances of the upper and lower surfaces, respectively. Moreover, as shown in FIG. 6, when the shielding plate 340 is placed between the two printed circuit boards 361 and 362, the two printed circuit boards 361 and 362 causing the change in impedance do not affect each other, thus increasing the stability of the portable device 300 operating at high speed. Although not shown in FIG. 6, the shielding plate 340 may be added between the printed circuit board 361 and the first proximity sensors 321 to 32n and between the printed circuit board 362 and the second proximity sensors 331 to 33n, respectively, such that the change in impedance caused by the printed circuit boards 361 and 362 may not affect the first and second proximity sensors 321 to 32n and 331 to 33n. In FIG. 6, a distance (air gap) between the printed circuit board 361 and 362 and the proximity sensors 321 to 32n and 331 to 33n plays the same role of shield plate. The air gap that is low dielectric can be shield plate if shield plate is not necessary to connect to a ground potential.

Although FIG. 6 shows that a predetermined distance (for example, 0.5 mm) is maintained between the printed circuit boards 361 and 362 and the shielding plate 340, respectively, it is possible to further reduce the distance between the printed circuit boards 361 and 362 and the shielding plate 340 by inserting a material having a low dielectric constant such as air between the printed circuit boards 361 and 362 and the shielding plate 340, if downsizing of the portable device is an important factor.

As a method of detecting proximity using the portable device 300 of FIG. 6, the plurality of first proximity sensors 321 to 32n and the plurality of second proximity sensors 331 to 33n respectively detect the proximity, in a similar manner to the portable device 100 of FIG. 2. If all of the first proximity sensors 321 to 32n do not detect the proximity within a predetermined period of time (for example, 1 msec), if the sum of impedances detected by all of the first proximity sensors 321 to 32n is smaller than a first reference impedance value (IMPthu), or if the difference in impedance detected by all of the first proximity sensors 321 to 32n is greater than a predetermined value, the controller of the portable device 300 determines that the upper case 311 of the portable device 300 is placed toward a conductive surface 380, and thus activates only the second proximity sensors 331 to 33n and deactivates all or a portion of the first proximity sensors 321 to 32n. On the other hand, if all of the second proximity sensors 331 to 33n do not detect the proximity within a predetermined period of time (for example, 1 msec), if the sum of impedances detected by all of the second proximity sensors 331 to 33n is smaller than a second reference impedance value (IMPthd), or if the difference in impedance detected by all of the second proximity sensors 331 to 33n is greater than a predetermined value, the controller of the portable device 300 determines that the lower case 312 of the portable device 300 is placed toward the conductive surface 380, and thus activates only the first proximity sensors 321 to 32n and deactivates all or a portion of the second proximity sensors 331 to 33n. In the same manner as FIG. 2, the first reference impedance value IMPthu may be set to the sum of average impedances previously detected by the plurality of first proximity sensors 321 to 32n m times (m being a natural number). Likewise, the second reference impedance value IMPthd may be set to the sum of average impedances previously detected by the plurality of second proximity sensors 331 to 33n m times (m being a natural number). Moreover, the difference in impedance detected by the first proximity sensors 321 to 32n may be set to a difference in impedance previously detected m times (m being a natural number).

In a similar manner as shown in FIG. 4, after the impedances of the upper surface and the lower surface are measured for a predetermined period of time, the controller of the portable device 300 compares an average upper impedance value AIMPu detected by the first proximity sensors 321 to 32n and an average lower impedance value AIMPd detected by the second proximity sensors 331 to 33n and, if the average upper impedance value AIMPu is smaller than the average lower impedance value AIMPd, allows only the second proximity sensors 331 to 33n to detect the proximity of a user. However, if the average upper impedance value AIMPu is equal to or greater than the average lower impedance value AIMPd, the controller allows only the first proximity sensors 321 to 32n to detect the proximity of a user.

Since the portable device 300 of FIG. 6 includes the plurality of first proximity sensors 321 to 32n and the plurality of second proximity sensors 331 to 33n, it is possible to arrange the plurality of first and second proximity sensors 321 to 32n and 331 to 33n in the form of a matrix so as to detect the approach direction of a user. However, since the portable device 30 is held in the user's hand during use in most cases, it is rare to detect the proximity of a user to the lower surface of the portable device 300. Accordingly, the number of the second proximity sensors 331 to 33n may not be the same as that of the first proximity sensors 321 to 32n. That is, the number of the second proximity sensors 331 to 33n may be smaller than that of the first proximity sensors 321 to 32n.

Moreover, when the portable device 300 includes a plurality of touch sensors, most of the touch sensors are placed on the upper case 311 of the portable device 300. Therefore, it is possible to use the impedance sensing-type touch sensors as the first proximity sensors 321 to 32n by setting the sensitivity of the impedance sensing-type touch sensors at a high level as mentioned above. Thus, the portable device including the touch sensors may be implemented by adding the second proximity sensors 331 to 33n. On the other hand, when the first and second proximity sensors 321 to 32n and 331 to 33n do not detect the proximity, they can be used as the touch sensors.

Although examples in which the proximity sensors are provided at the top or at the top and bottom of the portable device have been described, the proximity sensor may be provided at the side thereof, if necessary.

The foregoing description of the exemplary embodiments of the present invention has been presented for the purpose of illustration and description. It is not intended to be exhaustive or to limit the invention to the precise form disclosed, and modifications and variations are possible in light of the above teachings or may be acquired from practice of the invention. It is intended that the scope of the invention be defined by the claims appended hereto and their equivalents.

1. A portable device with a proximity sensor, comprising:
upper and lower cases;
at least one printed circuit board placed between the upper and lower cases and including a controller;
at least one first proximity sensor placed between the upper case and the at least one printed circuit board and configured to detect impedance;
at least one second proximity sensor placed between the lower case and the at least one printed circuit board and configured to detect impedance; and
at least one shielding means placed between the at least one first proximity sensor and the at least one second proximity sensor such that impedance applied through the lower case is prevented from being applied to the first proximity sensor and impedance applied through the upper case is prevented from being applied to the second proximity sensor.

2. The portable device of claim 1, wherein the at least one shielding means is a conductive plate electrically connected to a ground voltage.

3. The portable device of claim 2, further comprising an insulating plate having a low dielectric constant and placed between the at least one shielding means and the at least one printed circuit board.

4. The portable device of claim 1, wherein the at least one shielding means is an insulating plate having a low dielectric constant.

5. The portable device of claim 1, wherein the at least one shielding means forms an empty space of a predetermined distance between the first and second proximity sensors.

6. The portable device of claim 1, wherein, when the printed circuit board is a multi-layered printed circuit board, the at least one shielding means is implemented as one layer of the multi-layered printed circuit board.

7. The portable device of claim 1, wherein, when there are provided a plurality of printed circuit boards, the at least one shielding means is placed between the plurality of printed circuit boards.

8. The portable device of claim 1, wherein the at least one shielding means is placed between the at least one printed circuit board, and the first and second proximity sensors, respectively.

9. The portable device of claim 1, wherein the controller compares impedance values detected by the first and second proximity sensors for a predetermined period of time, deactivates the first proximity sensor when the impedance value detected by the first proximity sensor is smaller than the impedance value detected by the second proximity sensor, and deactivates the second proximity sensor when the impedance value detected by the first proximity sensor is equal to or greater than the impedance value detected by the second proximity sensor.

10. The portable device of claim 1, wherein the controller compares changes in impedance values measured by the first and second proximity sensors a plurality of times for a predetermined period of time, deactivates the second proximity sensor when the change in impedance values detected by the first proximity sensor is greater than the change in impedance values detected by the second proximity sensor, and deactivates the first proximity sensor when the change in impedance values detected by the first proximity sensor is equal to or smaller than the change in impedance values detected by the second proximity sensor.

11. The portable device of claim 1, wherein, when the first proximity sensors and the second proximity sensors are provided in plural, the controller deactivates the plurality of second proximity sensors when all of the plurality of first proximity sensors detect proximity within a predetermined period of time, and deactivates the plurality of first proximity sensors when all of the plurality of second proximity sensors detect proximity within a predetermined period of time.

12. The portable device of claim 1, wherein, when the first proximity sensors and the second proximity sensors are provided in plural, the controller deactivates the plurality of first proximity sensors when the sum of impedances detected by the plurality of first proximity sensors is smaller than a first reference impedance value, and deactivates the plurality of second proximity sensors when the sum of impedances detected by the plurality of second proximity sensors is smaller than a second reference impedance value.

13. The portable device of claim 12, wherein the first and second reference impedance values are the sum of average impedance values previously detected by the plurality of first proximity sensors a plurality of times and the sum of average impedance values previously detected by the plurality of second proximity sensors a plurality of times, respectively.

14. The portable device of claim 1, wherein, when the first proximity sensors and the second proximity sensors are provided in plural, the controller deactivates the plurality of first proximity sensors when a difference in impedance detected by the plurality of first proximity sensors is equal to or smaller than a first reference impedance value, and deactivates the plurality of second proximity sensors when a difference in impedance detected by the plurality of second proximity sensors is equal to or smaller than a second reference impedance value.

15. The portable device of claim 14, wherein the first and second reference impedance values are the difference of average impedance values previously detected by the plurality of first proximity sensors a plurality of times and the difference of average impedance values previously detected by the plurality of second proximity sensors a plurality of times, respectively.

16. The portable device of claim 1, wherein, when the first proximity sensors and the second proximity sensors are provided in plural, the plurality of first proximity sensors and the plurality of second proximity sensors are arranged in the form of a matrix, respectively.

17. The portable device of claim 16, wherein the controller determines an approach direction of a user according to the order that the plurality of first and second proximity sensors detect proximity of the user.

18. The portable device of claim 1, wherein the first and second proximity sensors are used as touch sensors during deactivation.

19. A portable device with a proximity sensor, comprising:
upper and lower cases;
at least one printed circuit board placed between the upper and lower cases and including a controller;
a plurality of proximity sensors placed between the upper case and the at least one printed circuit board and configured to detect impedance; and
at least one shielding means placed between the plurality of proximity sensors and the at least one printed circuit board such that impedance applied through the lower case is prevented from being applied to the plurality of proximity sensors.

20. The portable device of claim 19, wherein the at least one shielding means is a conductive plate electrically connected to a ground voltage.

21. The portable device of claim 20, further comprising an insulating plate having a low dielectric constant and placed between the at least one shielding means and the at least one printed circuit board.

22. The portable device of claim 19, wherein the at least one shielding means is an insulating plate having a low dielectric constant.

23. The portable device of claim 19, wherein the at least one shielding means forms an empty space of a predetermined distance between the plurality of proximity sensors and the at least one printed circuit board.

24. The portable device of claim 19, wherein, when the printed circuit board is a multi-layered printed circuit board, the at least one shielding means is implemented as one layer of the multi-layered printed circuit board.

25. The portable device of claim 19, wherein, when there are provided a plurality of printed circuit boards, the at least one shielding means is placed between the plurality of printed circuit boards.

26. The portable device of claim 19, wherein the controller deactivates the plurality of proximity sensors when all of the plurality of proximity sensors detect proximity within a predetermined period of time.

27. The portable device of claim 19, wherein the controller deactivates the plurality of proximity sensors when the sum of impedances detected by the plurality of proximity sensors is smaller than a reference impedance value.

28. The portable device of claim 27, wherein the reference impedance value is the sum of average impedance values previously detected by the plurality of proximity sensors a plurality of times.

29. The portable device of claim 19, wherein the controller deactivates the plurality of proximity sensors when a difference in impedance detected by the plurality of proximity sensors is equal to or greater than a reference impedance value.

30. The portable device of claim 29, wherein the reference impedance value is the difference of average impedance values previously detected by the plurality of proximity sensors a plurality of times.

31. The portable device of claim 19, wherein the plurality of proximity sensors are arranged in the form of a matrix.

32. The portable device of claim 31, wherein the controller determines an approach direction of a user according to the order that the plurality of proximity sensors detect proximity of the user.

33. The portable device of claim 19, wherein the plurality of proximity sensors are used as touch sensors during deactivation.
